(19) United States
(12) Patent Application Publication
(10) Pub. No.: US 2015/0132866 A1
(43) Pub. Date: May 14, 2015

(54) Silicon Wafer Coated With A Passivation Layer

(71) Applicant: Dow Corning Corporation, Midland, MI (US)

(72) Inventors: Syed Salman Asad, Ixelles (BE); Guy Beaucarne, Oud-Heverlee (BE); Pierre Descamps, Rixensart (BE); Vincent Kaiser, Pipaix (BE); Patrick Leempoel, Bruxelles (Uccle) (BE)

(73) Assignee: DOW CORNING CORPORATION, Midland, MI (US)

(21) Appl. No.: 14/402,249

(22) PCT Filed: Apr. 25, 2013
(86) PCT No.: PCT/US13/38102

§ 371 Date: Nov. 19, 2014

(30) Foreign Application Priority Data
May 31, 2012 (GB) 1209693.9
Mar. 13, 2013 (GB) 1304484.7

(51) Int. Cl. H01L 21/02; H01L 21/66

(52) U.S. Cl. CPC H01L 21/02164; H01L 21/0234; H01L 21/02208; H01L 22/10
USPC 438/14

(57) ABSTRACT

Production of a silicon wafer coated with a passivation layer. The coated silicon wafer may be suitable for use in photovoltaic cells which convert energy from light impinging on the front face of the cell into electrical energy.

This invention relates to the production of a silicon wafer coated with a passivation layer. It is particularly concerned with coated silicon wafers suitable for use in photovoltaic cells which convert energy from light impinging on the front face of the cell into electrical energy. (The front face of a photovoltaic cell is the major surface facing the light source and the opposite major surface is the back surface.)

Photovoltaic cells are widely used as solar cells for providing electricity from impinging sunlight. Significant cost reduction of silicon solar cells requires a high throughput, low cost, and reliable industrial process on thin silicon wafer substrates. The thickness of the silicon wafer processed in mass production of solar cells has progressively decreased and is now about 180 μm; it is expected to be about 120 μm by 2020. This imposes significant modifications to the architecture of the solar cell because of cell bowing and loss of conversion efficiency. Cell bowing may result from a mismatch of the coefficients of thermal expansion of materials used in the cell.

Present industrial surface conditioning and back surface passivation processes do not meet the requirements for yield and performance on thin substrates. The currently dominating technology of Aluminum Back Surface Field (BSF) cell architecture, has reached its limits, particularly because of excessive cell bowing with wafers having thicknesses below about 200 μm following the high temperature (800° C.+) co-firing step generally used in solar cell production. Another issue is a loss in conversion efficiency due to creation of defect rich zone (electron-hole recombination zone) in the region where aluminum diffuses into silicon at the back of the cell. As the wafer becomes thinner, this defective region may represent an increasingly significant fraction of the total active device thickness. Alternatives are hence required, particularly for back surface passivation.

One alternative solution relies on the use of dielectric layers for the passivation of the back surface, at least one of the layers of the stack being hydrogen rich to be used as a hydrogen source for dangling bonds passivation.

A paper by M. Tucci et al in Thin Solid Films (2008), 516(20), pages 6939-6942 describes thermal annealing after the sequential deposition by plasma enhanced chemical vapour deposition (PECVD) of a stack of hydrogenated amorphous silicon and hydrogenated amorphous silicon nitride to ensure stable passivation.

WO-A-2007/055484 and WO-A-2008/07828 disclose an alternative stack made of a silicon oxy-nitride (SiOₓN_{y}) passivation layer and a silicon nitride anti-reflective layer deposited on the back of the cell for surface passivation and optical trapping. The passivation layer is 10-50 nm thick while the anti-reflective layer is 50-100 nm thick.

WO-A-2006/110048 (US-A-2009/056800) discloses the deposition of a thin hydrogenated amorphous silicon or hydrogenated amorphous silicon carbide film, followed by the deposition of a thin hydrogenated silicon nitride film, preferably by PECVD (Plasma Enhanced Chemical vapor deposition) prior to a final anneal at high temperature in forming gas.

US-A-2007/0137699 describes a method for fabricating a solar cell comprising treating a silicon substrate in a plasma reaction chamber, forming a high efficiency emitter structure on the front face of the silicon substrate and forming a passivated structure on the second surface of the silicon substrate. The passivated back surface structure, comprising at least a SiO₂ layer and eventually also a hydrogenated amorphous silicon nitride layer, is made by PECVD at 120-240° C., introducing silane (SiH₄) and another reactive gas prior to igniting the plasma. The operating pressure ranges from 200 to 800 mTorr. SiO₂ is formed first, using oxygen as other reactive gas, directly on the back of the silicon wafer. The layer may be topped by a layer of silicon nitride made by introducing ammonia (NH₃) as other reactive gas.

US-A-2010/0323503 describes depositing a thin (0.1 to 10 nm) amorphous hydrogenated silicon layer on the surface to be passivated and converting it to SiO₂ by rapid thermal processing in an oxygen environment at between 750° C. and 1200° C. for 5 seconds to 30 minutes.

U.S. Pat. No. 7,838,400 describes forming a thin (2-15 nm) silicon oxide layer by rapidly heating the substrate at a rate of 200-400° C./second to a temperature of 800-1200° C. in the presence of oxygen and hydrogen at a pressure of 0.1-10 Torr and maintaining enough time to diffuse dopant previously deposited on one of the face of the substrate.

In Proceedings—Electrochemical Society (2003), 2003-1(Dielectrics in Emerging Technologies), 315-322, Journal of Applied Physics (2003), 94(5), 3427-3435 and

Materials Research Society Symposium Proceedings (2002), 716(Silicon Materials—Processing, Characterization and Reliability), 569-574, A. Grill and co-workers describe the deposition of low k dielectric (a low dielectric constant oxide, lower than k of dense SiO₂) to be used for the microelectronic market. SiOC films are deposited from an organosilicon compound precursor and an additional organic material to deposit carbon rich SiOC. The additional organic material is chosen so that firing is accompanied by the elimination of thermally less stable organic fractions, thus creating a certain amount of porosity and hence decreasing the film density.

WO-A-2006/097303 and US-A-2009/0301557 describe a method for the production of a photovoltaic device, for instance a solar cell, by depositing a dielectric layer on the rear surface of a semiconductor substrate and depositing a passivation layer comprising hydrogenated SiN on top of the dielectric layer to form a stack and forming back contacts through this stack.

WO-A-2006/048649, WO-A-2006/048650 and WO-A-2012/010299 describe generating a non-equilibrium atmospheric pressure plasma incorporating an atomized surface treatment agent by applying a radio frequency high voltage to at least one electrode positioned within a dielectric housing having an inlet and an outlet while causing a process gas to flow from the inlet past the electrode to the outlet. The electrode is combined with an atomizer for the surface treatment agent within the housing. The non-equilibrium atmospheric pressure plasma extends from the electrode at least to the outlet of the housing so that a substrate placed adjacent to the outlet is in contact with the plasma.

A process according to the present invention for the production of a silicon wafer coated with a passivation layer of a silicon oxide comprises the steps of
(i) depositing a layer of density at least 1050 kg/m³ of a silicon compound containing 5 to 66% carbon atoms (calculated as the proportion of carbon atoms in the deposited layer to total atoms excluding hydrogen as measured by X-ray photoelectron spectroscopy) on a silicon wafer substrate and
(ii) thermally treating the deposited layer of silicon compound in an oxygen-containing atmosphere at a temperature of at least 600° C. for 1 to 60 seconds, during which treatment the deposited layer is subject to a maximum temperature in the range 600 to 1050° C.

Unless otherwise indicated the density of the film is measured by:
1) measuring film thickness using a spectroscopic ellipsometer UVsel from Jobin-Yvon.
2) measuring the film weight using a weighing scale with a precision of 10⁻⁶ g
3) using the wafer surface area provided by manufacturer to determine the volume and then determining the film density.

The invention includes a process for the production of a photovoltaic cell, wherein a silicon wafer coated with a passivation layer of a silicon oxide is produced by the process described above, the silicon oxide layer is hydrogenated, and back contacts are formed through the silicon oxide layer.

The proportion of carbon atoms in the deposited layer to total atoms excluding hydrogen is measured by X-ray photoelectron spectroscopy (XPS). X-ray photoelectron spectroscopy (XPS) involves irradiation of a sample with soft X-rays, and the energy analysis of photo-emitted electrons that are generated close to the sample surface. XPS has the ability to detect all elements (with the exception of hydrogen and helium) in a quantitative manner from an analysis depth of 10 nm (or less). In addition to elemental information XPS can also be used to probe the chemical state of elements through the concept of binding energy shift. XPS analysis can be performed using an Axis Ultra spectrometer (Kratos Analytical).

The silicon wafer substrate which is coated is generally crystalline and can be mono-crystalline or multi-crystalline silicon. A mono-crystalline wafer can for example be a float-zone (FZ) silicon wafer, a Czochralski process (CZ) silicon wafer or a quasi-mono type silicon wafer. The silicon wafer substrate can for example be 100 μm to 400 μm thick; for lifetime and CV measurement, wafer ˜300 nm thick were preferred while 200 nm thick wafers were used for testing material at cell level. The symbol “˜” means approximately or about.

The layer of silicon compound deposited in step (i) has a density at least 1050 kg/m³, alternatively in the range 1200 to 2000 kg/m³, alternatively 1500 to 2000 kg/m³. This is higher than the density of most organosilicon compounds, but lower than the density of a dielectric silica layer. The thickness of the layer of silicon compound deposited in step (i) is preferably at least 50 nm, for example at least 100 nm, and may be up to 1 μm. The thickness of the layer deposited is more alternatively 200 nm to 600 nm.

In one type of preferred process according to the invention, the layer of silicon compound deposited in step (i) is formed from an organosilicon compound precursor. Examples of suitable organosilicon compounds include low molecular weight linear siloxanes such as hexamethyldisiloxane ((CH₃)₃)Si)₂O, octamethyltrisiloxane or decamethyltetrasiloxane, including siloxanes containing one or more Si—H group such as heptamethyltrisiloxane, low molecular weight poly(methylhydrogensiloxane) and low molecular weight dimethylsiloxane methylhydrogensiloxane copolymers, cyclosiloxanes such as cyclooctamethyltetrasiloxane, cyclodecamethylpentasiloxane or tetramethylcyclotetrasiloxane (CH₃(H)SiO)₄, alkoxysilanes such as tetraethoxysilane (ethylorthosilicate) Si(OC₂H₅)₄ or methyltrimethoxysilane. The organosilicon compound precursor preferably contains silicon, carbon, oxygen and hydrogen atoms. The silicon compound deposited in step (i) preferably comprises silicon, oxygen and carbon atoms and optionally hydrogen atoms

The layer of silicon compound deposited in step (i) can be formed by chemical modification of the organosilicon compound precursor, for example by a polymerisation process which comprises siloxane condensation and/or an oxidation process. The layer of silicon compound deposited preferably has a lower carbon content than the organosilicon compound precursor, but we have found that the layer of silicon compound, after thermal treatment in step (ii), forms a dielectric coating layer of improved passivation properties if the layer of silicon compound deposited contains at least 5% carbon.

In one preferred method of carrying out step (i), the layer of silicon compound is deposited from a non-local thermal equilibrium atmospheric pressure plasma interacting with an organosilicon compound. The layer of silicon compound may comprise a product of the interaction (e.g., plasma generated activated species and/or fragments of the organosilicon compound). Alternative methods of depositing the layer of silicon compound include low pressure plasma deposition and deposition and cross-linking of wet chemicals.

Plasma can in general be any type of non-equilibrium atmospheric pressure plasma. A preferred example is a non-local thermal equilibrium atmospheric pressure plasma discharge including dielectric barrier discharge and diffuse dielectric barrier discharge such as glow discharge plasma.

In an alternative type of preferred process according to the invention, the silicon compound deposited in step (i) is a silicon-containing polymer having Si—H groups. We have found that a silicon-containing polymer having Si—H groups is readily converted by thermal treatment into a dielectric silicon dioxide layer suitable for forming a passivated silicon dielectric interface.

The silicon-containing polymer having Si—H groups preferably comprises a silsesquioxane resin of the empirical formula RSiO_{3/2} wherein the groups R are selected from hydrogen and hydrocarbyl groups. The silicon-containing polymer having Si—H groups can for example be a silsesquioxane resin having Si—H groups and hydrocarbon groups bonded to silicon. One example of a resin having Si—H groups and hydrocarbon groups bonded to silicon is a hydrogen methyl silsesquioxane resin comprising HSiO_{3/2} units and CH₃SiO_{3/2} units. Such a resin can be prepared by hydrolysis of a mixture of HSiCl₃ and CH₃SiCl₃. Alternative examples of a resin having Si—H groups and hydrocarbon groups bonded to silicon are resins comprising HSiO_{3/2} units and (CH₃)HSiO_{3/2} units and resins comprising HSiO_{3/2} units, (CH₃)HSiO_{2/2} units and CH₃SiO_{3/2} units. Such resins can be prepared by hydrolysis of a mixture of HSiCl3 (CH₃)HSiCl₂ and optionally CH₃SiCl₃. Alternatively the silicon-containing polymer having Si—H groups can be a mixture of hydrogen silsesquioxane resin with a silicon-containing polymer having hydrocarbon groups bonded to silicon, for example be another silsesquioxane resin such as methyl silsesquioxane resin of empirical formula CH₃SiO_{3/2} or an organopolysiloxane containing RHSiO_{2/2} siloxane units where R represents a hydrocarbyl group, preferably an alkyl group having 1 to 6 carbon atoms, for example be a poly(methylhydrogensiloxane). The proportion of carbon atoms to total atoms excluding hydrogen as measured by XPS in the layer deposited from any resin or mixture of silicon-containing polymers applied in step (i) is at least 5%.

In a process for depositing the layer of silicon compound on a silicon wafer substrate from a non-local thermal equilibrium atmospheric pressure plasma, the process may for example comprise applying a radio frequency high voltage to at least one needle electrode positioned within a dielectric housing having an inlet and an outlet while causing a process gas to flow from the inlet through a channel past the electrode to the outlet, thereby generating a non-local thermal equilibrium atmospheric pressure plasma, incorporating an organosilicon compound in the non-local thermal equilibrium atmospheric pressure plasma so that the organosilicon compound interacts with the non-local thermal equilibrium atmospheric pressure plasma, and positioning the silicon wafer substrate adjacent to the outlet of the dielectric housing so that the surface of the silicon wafer substrate is in contact with activated organosilicon compound species and organosilicon compound fragments generated by plasma-organosilicon compound interaction.

The non-local thermal equilibrium atmospheric pressure plasma may extend from the electrode to the outlet of the dielectric housing so that the surface of the silicon wafer substrate adjacent to the outlet of the dielectric housing is in contact with the plasma. However the plasma need not extend to the outlet of the dielectric housing provided that the silicon wafer substrate is in contact with activated organosilicon compound species and organosilicon compound fragments generated by plasma-organosilicon compound interaction. Such activated organosilicon compound species and organosilicon compound fragments can be conveyed by the process gas flow, diffusion and possibly the electric field to the surface of the silicon wafer substrate.

Such a non-local thermal equilibrium atmospheric pressure plasma process will be described with reference to the accompanying drawings, of which

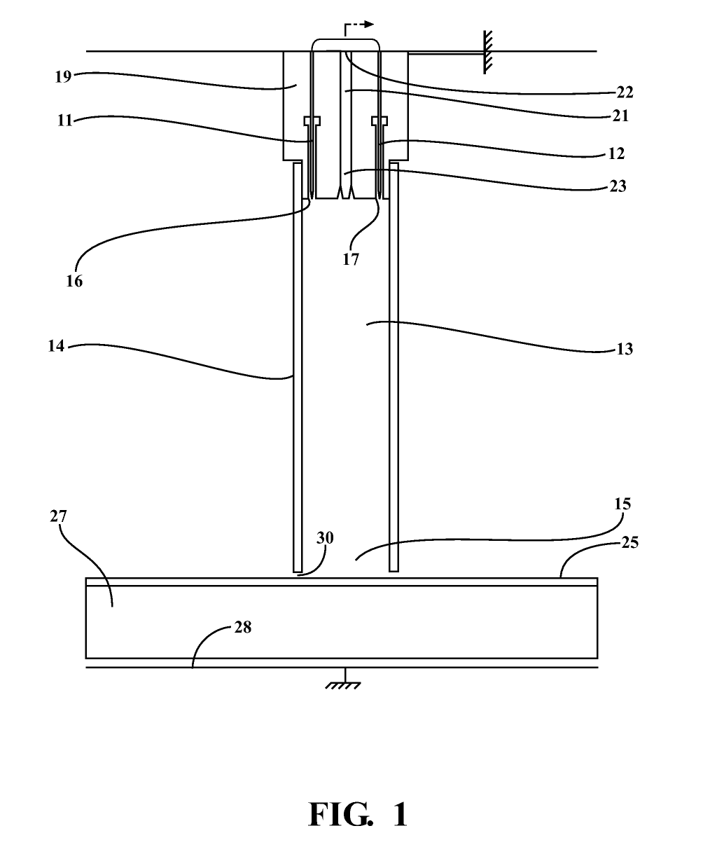

FIG. 1 is a diagrammatic cross section of an apparatus according to the invention for generating a non-equilibrium atmospheric pressure plasma incorporating an atomised organosilicon compound;

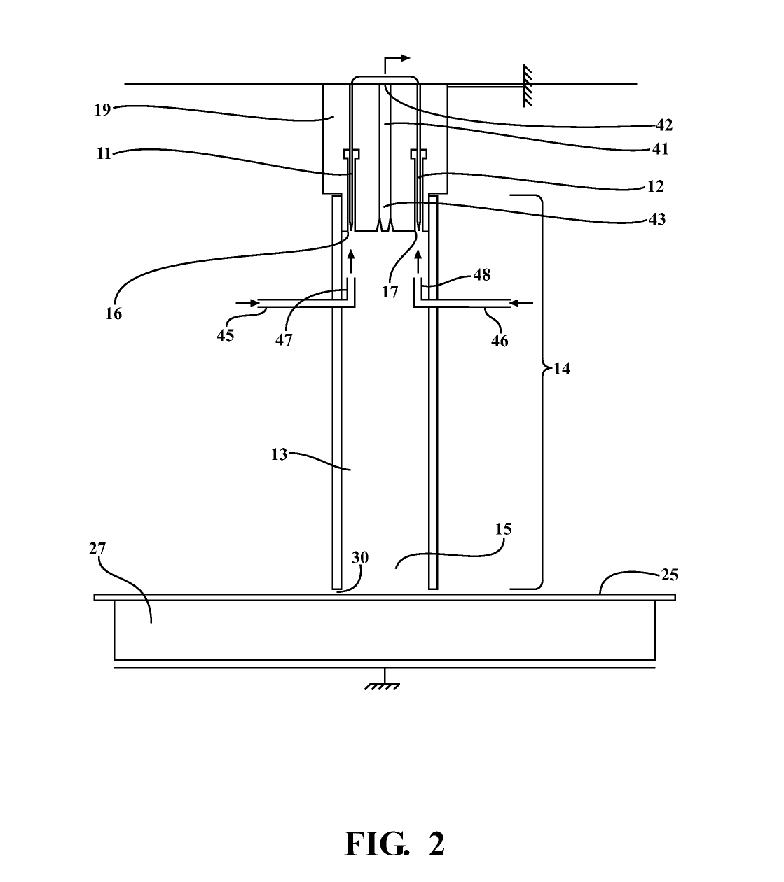

FIG. 2 is a diagrammatic cross section of an alternative apparatus according to the invention for depositing a silicon compound layer from a non-equilibrium atmospheric pressure plasma incorporating an atomised organosilicon compound;

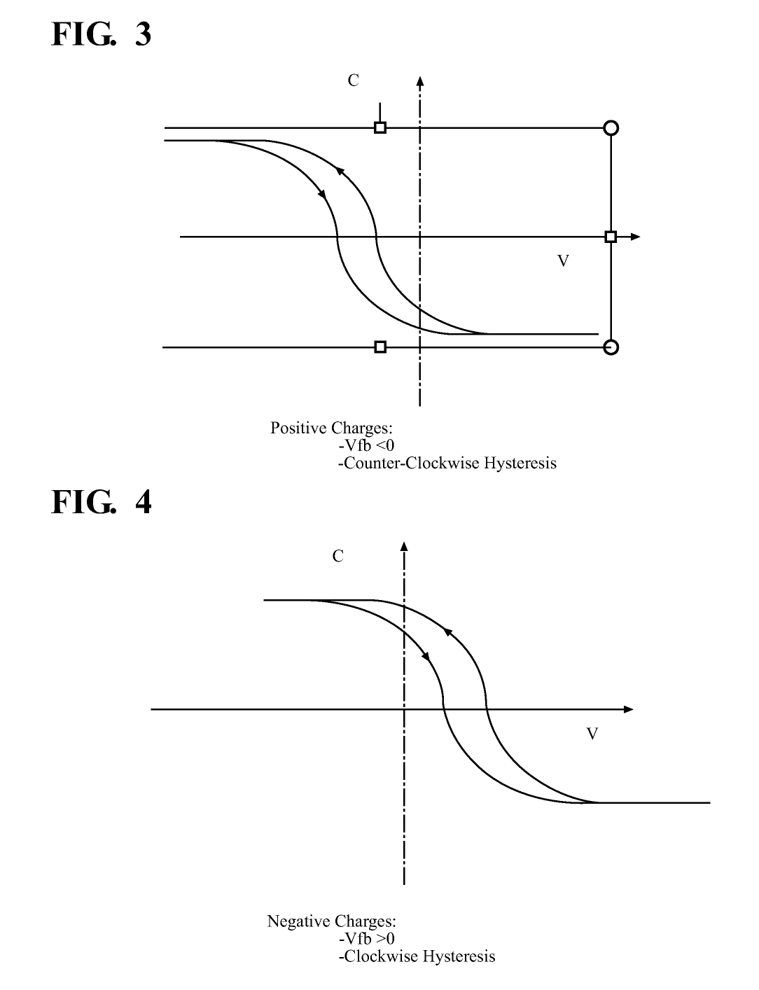

FIG. 3 is a graph plotting capacitance against voltage applied to a complementary metal-oxide-semiconductor structure (CMOS) comprising a p-doped FZ (float zone silicon) wafer and an oxide having positive charges; and

FIG. 4 is a graph plotting capacitance against voltage applied to a CMOS structure comprising a p-doped FZ wafer and an oxide having negative charges.

The apparatus of FIG. 1 comprises two electrodes (11, 12) positioned within a plasma tube (13) defined by a dielectric housing (14) and having an outlet (15). The electrodes (11, 12) are needle electrodes both having the same polarity and are connected to a suitable power supply. Although the power supply to the electrode or electrodes may operate at any frequency between 0 to 14 MHz (0 MHz means direct current discharge), it is preferably a low to radio frequency power supply as known for plasma generation, which is in the range 3 kHz to 300 kHz. The root mean square potential of the power supplied is generally in the range 1 kV to 100 kV, alternatively between 4 kV and 30 kV.

The electrodes (11, 12) are each positioned within a narrow channel (16 and 17 respectively), for example of radius 0.1 to 5 mm, alternatively 0.2 to 2 mm, greater than the radius of the electrode, communicating with plasma tube (13). Each channel (16, 17) has an entry which forms the inlet for process gas into the apparatus and an exit into the plasma tube (13). Each channel (16, 17) preferably has a ratio of length to hydraulic diameter greater than 10:1. The tip of each needle electrode (11 and 12) is positioned close to the exit of the associated channel (16 and 17 respectively). Preferably the needle electrode extends from the channel entry and projects outwardly from the channel (16, 17) so that the tip of the needle electrode is positioned in the dielectric housing close to the exit of the channel at a distance outside the channel of at least 0.5 mm up to 5 times the hydraulic diameter of the channel.

The process gas is fed to a chamber (19) whose outlets are the channels (16, 17) surrounding the electrodes. The chamber (19) is made of a heat resistant, electrically insulating material which is fixed in an opening in the base of a metal box. The metal box is grounded but grounding of this box is optional. The chamber (19) can alternatively be made of an electrically conductive material, provided that all the electrical connections are insulated from the ground, and any part in potential contact with the plasma is covered by a dielectric.

An atomiser (21) having an inlet (22) for organosilicon compound is situated adjacent to the electrode channels (16, 17) and has atomising means (not shown) and an outlet (23) feeding atomised organosilicon compound to the plasma tube (13). The chamber (19) holds the atomiser (21) and needle electrodes (11, 12) in place.

The dielectric housing (14) can be made of any dielectric material. Experiments described below were carried out using quartz dielectric housing (14) but other dielectrics, for example glass or ceramic or a plastic material such as polyamide, polypropylene or polytetrafluoroethylene, for example that sold under the trade mark ‘Teflon’, can be used. The dielectric housing (14) can be formed of a composite material, for example a fibre reinforced plastic designed for high temperature resistance.

The silicon wafer substrate (25) to be coated is positioned at the plasma tube outlet (15). The silicon wafer substrate (25) is laid on a support (27, 28). The silicon wafer substrate (25) is arranged to be movable relative to the plasma tube outlet (15). The support (27, 28) can for example be a dielectric layer (27) covering a metal supporting plate (28). The dielectric layer (27) is optional. The metal plate (28) as shown is grounded but grounding of this plate is optional. If the metal plate (28) is not grounded, this may contribute to the reduction of arcing onto the silicon wafer substrate (25). The gap (30) between the outlet end of the dielectric housing (14) and the silicon wafer substrate (25) is the only outlet for the process gas fed to the plasma tube (13). The surface area of the gap (30) between the outlet of the dielectric housing and the substrate is preferably less than 35 times the area of the inlet or inlets for process gas. If the dielectric housing has more than one inlet for process gas, as in the apparatus of FIG. 1 which has inlet channels (16) and (17), the surface area of the gap between the outlet of the dielectric housing and the substrate is preferably less than 35 times the sum of the areas of the inlets for process gas.

As an electric potential is applied to the electrodes (11, 12), an electric field is generated around the tips of the electrodes which ionizes the gas to form plasma. The sharp point at the tips of the electrodes aids the process, as the electric field density is inversely proportional to the radius of curvature of the electrode. Needle electrodes (such as 11, 12) possess the benefit of creating a gas breakdown using a lower voltage source because of the enhanced electric field at the sharp extremity of the needles.

The plasma generating apparatus described can operate without special provision of a counter electrode. Alternatively a grounded counter electrode may be positioned at any location along the axis of the plasma tube.

The power supply to the electrode or electrodes is a low frequency power supply as known for plasma generation, that is in the range 3 kHz to 300 kHz. Our most preferred range is the very low frequency (VLF) 3 kHz-30 kHz band, although the low frequency (LF) 30 kHz-300 kHz range can also be used successfully. One suitable power supply is the Haiden Laboratories Inc. PHF-2K unit which is a bipolar pulse wave, high frequency and high voltage generator. It has a faster rise and fall time (<3 μs) than conventional sine wave high frequency power supplies. Therefore, it offers better ion generation and greater process efficiency. The frequency of the unit is also variable (1-100 kHz) to match the plasma system. An alternative suitable power supply is an electronic ozone transformer such as that sold under the reference ETI110101 by the company Plasma Technics Inc. It works at fixed frequency and delivers a maximum power of 100 Watt with a working frequency of 20 kHz.

The atomiser (21) preferably uses a gas to atomise the organosilicon compound. For example the process gas used for generating the plasma is used as the atomizing gas to atomise the organosilicon compound. The atomizer (21) can for example be a pneumatic nebuliser, particularly a parallel path nebuliser such as that sold by Burgener Research Inc. of Mississauga, Ontario, Canada, under the trade mark An Mist HP, or that described in U.S. Pat. No. 6,634,572. The atomizer can alternatively be an ultrasonic atomizer in which a pump is used to transport the liquid organosilicon compound into an ultrasonic nozzle and subsequently it forms a liquid film onto an atomising surface. Ultrasonic sound waves cause standing waves to be formed in the liquid film, which result in droplets being formed. The atomiser preferably produces drop sizes of from 1 to 100 μm, alternatively from 1 to 50 μm. Suitable atomisers for use in the present invention include ultrasonic nozzles from Sono-Tek Corporation, Milton, N.Y., USA. Alternative atomisers may include for example electrospray techniques, methods of generating a very fine liquid aerosol through electrostatic charging. The most common electrospray apparatus employs a sharply pointed hollow metal tube, with liquid pumped through the tube. A high-voltage power supply is connected to the outlet of the tube. When the power supply is turned on and adjusted for the proper voltage, the liquid being pumped through the tube transforms into a fine continuous mist of droplets. Inkjet technology can also be used to generate liquid droplets without the need of a carrier gas, using thermal, piezoelectric, electrostatic and acoustic methods.

While it is preferred that the atomiser (21) is mounted within the housing (14), for example surrounded by the chamber (19), an external atomiser can be used. This can for example feed an inlet tube having an outlet in similar position to outlet (23) of nebuliser (21). Alternatively the organosilicon compound, for example in a gaseous state, can be incorporated in the flow of process gas entering chamber (19) either from the channels (17) or through a tube positioned at the location of the nebulizer. In a further alternative the electrode can be combined with the atomizer in such a way that the atomizer acts as the electrode. For example, if a parallel path atomizer is made of conductive material, the entire atomizer device can be used as an electrode. Alternatively a conductive component such as a needle can be incorporated into a non-conductive atomizer to form the combined electrode-atomiser system.

The process gas flow from the inlet past the electrode preferably comprises helium or argon or another inert gas such as nitrogen, or a mixture of any of these gases with each other or with oxygen. Alternatively the process gas generally comprises from 50% by volume helium, argon or nitrogen, to 100% by volume helium, argon or nitrogen, alternatively from 50% to 99% optionally with up to 5 or 10% of another gas, for example oxygen. Specific examples of process gas mixtures which could be used are a mixture of 92% helium, 7.7% nitrogen and 0.3% oxygen, a mixture of 92% argon, 7.7% nitrogen and 0.3% oxygen could be used or alternatively a mixture of 98% nitrogen with 2% oxygen can be used. A higher proportion of an oxidizing gas such as oxygen can also be used if it is required to react with the organosilicon compound, sometimes no external oxygen is necessary as the oxygen atoms, if any, chemically bound within the organosilicon compound may participate in formation of oxide like film.

The velocity of the process gas flowing past the electrode through channels (16, 17) is preferably less than 100 m/s. The velocity of the process gas, for example helium flowing past the electrodes (11, 12) may be from 3.5 m/s to up to 70 m/s, alternatively at least 5 m/s up to 70 m/s or alternatively from 10 m/s to 50 m/s, alternatively from 10 m/s to 30 or 35 m/s. To promote turbulent gas flow in the plasma tube (13) and thus form a more uniform plasma, it may be preferred to also inject process gas into the dielectric housing at a velocity greater than 100 m/s. The ratio of process gas flow injected at a velocity greater than 100 m/s to process gas flowing past the electrode at less than 100 m/s is preferably from 1:20 to 5:1. If the atomiser (21) uses the process gas as the atomizing gas to atomise the surface treatment agent, the atomiser can form the inlet for the process gas injected at a velocity greater than 100 m/s. Alternatively the apparatus may have separate injection tubes for injecting helium process gas at a velocity of above 100 m/s.

The flow rate of the process gas flowing through the channels (16, 17) past the electrodes (11, 12) is preferably in a range of from 1 to 20 L/min, alternatively in the range 2 to 10 L/min. The flow rate of the process gas which has a velocity greater than 100 m/s, for example a process gas such as helium used as the atomising gas in a pneumatic nebulizer, is preferably in the range of 0.5 to 2.5 L/min or alternatively 0.5 to 2 L/min. When another process gas than helium is used, for example argon, a lower gas flow through the nebulizer can be used. Because of the much larger mass of argon versus helium the same atomisation performance is achieved with a gas flow 3 times lower. When using argon, gas flow through nebulizer is preferably in the range of 0.15 to 1.2 L/min.

The apparatus of FIG. 2 comprises two electrodes (11, 12) each positioned within a narrow channel (16 and 17 respectively) communicating with plasma tube (13) defined by a dielectric housing (14) and having an outlet (15), all as described above for FIG. 1. Helium process gas is fed to a chamber (19) whose outlets are the channels (16, 17) surrounding the electrodes. The substrate (25) to be treated is positioned at the plasma tube outlet (15) with a narrow gap (30) between the outlet end of the dielectric housing (14) and the substrate (25). The substrate (25) is laid on a dielectric support (27) and is arranged to be movable relative to the plasma tube outlet (15), as described with reference to FIG. 1.

The apparatus of FIG. 2 comprises an atomiser (41) having an inlet (42) for surface treatment agent, atomising means (not shown) and an outlet (43) feeding atomised surface treatment agent to the plasma tube (13). The atomiser (41) does not use gas to atomise the surface treatment agent.

The apparatus of FIG. 2 further comprises injection tubes (45, 46) for injecting helium process gas at a velocity of above 100 m/s. The outlets (47, 48) of the injection tubes (45, 46) are directed towards the electrodes (11, 12) so that the direction of flow of the high velocity process gas from injection tubes (45, 46) is counter to the direction of flow of process gas through channels (16, 17) surrounding the electrodes.

The atomiser (41) can for example be an ultrasonic atomizer in which a pump is used to transport the liquid surface treatment agent into an ultrasonic nozzle and subsequently it forms a liquid film onto an atomising surface. Ultrasonic sound waves cause standing waves to be formed in the liquid film, which result in droplets being formed. The atomiser preferably produces drop sizes of from 1 to 100 μm, more preferably from 1 to 50 μm. Suitable atomisers for use in the present invention include ultrasonic nozzles from Sono-Tek Corporation, Milton, N.Y., USA. Alternative atomisers may include for example electrospray techniques, methods of generating a very fine liquid aerosol through electrostatic charging. The most common electrospray apparatus employs a sharply pointed hollow metal tube, with liquid pumped through the tube. A high-voltage power supply is connected to the outlet of the tube. When the power supply is turned on and adjusted for the proper voltage, the liquid being pumped through the tube transforms into a fine continuous mist of droplets. Inkjet technology can also be used to generate liquid droplets without the need of a carrier gas, using thermal, piezoelectric, electrostatic and acoustic methods.

The organosilicon compound is preferably introduced into the non-local thermal equilibrium atmospheric pressure plasma at a flow rate of least 1 μL/min, alternatively at least 2 μL/min. The organosilicon compound can for example be introduced at a flow rate in a range of from 1 to 30 μL/min, alternatively from 2 to 20 μL/min. In a further alternative the organosilicon compound is introduced at 2 to 14 μL/min. The rates of deposition on the silicon wafer substrate of the layer of silicon compound from a non-local thermal equilibrium atmospheric pressure plasma using these feed rates of organosilicon compound are generally in the range 3 to 100 nm/s. A layer of powder free silicon compound can thereby be deposited at a much more rapid rate than a dense silicon oxide can be deposited.

As stated above, the layer of silicon compound deposited on the silicon wafer substrate contains at least 5% carbon but preferably has a lower carbon content than the organosilicon compound precursor. The highly energetic conditions in the non-local thermal equilibrium atmospheric pressure plasma promote partial conversion of the organosilicon compound into a silicate or silica structure with removal of carbon. For example, using the apparatus and flow rates disclosed above for generating the non-local thermal equilibrium atmospheric pressure plasma, the percentage of carbon atoms in the layer of silicon compound deposited from tetramethylcyclotetrasiloxane (CH₃(H)SiO)₄ as precursor is generally less than 33% and is usually in a preferred range of 5 to 30%. If the organosilicon compound precursor is Si(OC₂H₅₎₄ the percentage of carbon atoms in the layer deposited is less than 60%. If the organosilicon compound precursor is hexamethyldisiloxane the percentage of carbon atoms in the layer deposited is less than 66%. For all these precursors the percentage of carbon atoms in the layer of silicon compound deposited can be controlled to be in a preferred range, for example 5 to 30%, by varying the flow rates of the process gas, the energy supplied to the discharge and the organosilicon compound precursor within the preferred ranges described above.

An alternative method for deposition of a layer of density at least 1050 kg/m³ of a silicon compound containing 5 to 66% carbon atoms in step (i) of the invention is to use a low pressure plasma. The plasma is formed either in the absence of oxygen addition if the precursor molecule already contains oxygen atoms or adding a very small fraction of oxygen if the precursor is oxygen free and is operated at very low power. A silicon compound such as hexamethyldisiloxane or tetraethoxysilane is incorporated in the low pressure plasma and the silicon wafer substrate is positioned in contact with the plasma in the same manner as silicon wafer substrate (25) described above. This low pressure plasma method is however less advantageous than the non-local thermal equilibrium atmospheric pressure plasma method described above with reference to FIG. 1, because it requires expensive vacuum system and cannot easily be adapted for in-line processing.

In a further alternative method for deposition of a layer of density at least 1050 kg/m³ of a silicon compound containing 5 to 66% carbon atoms in step (i) of the invention, film can be deposited by a wet chemical route. For example a solution containing organo-metallic compound can be chemically polymerised and deposited on the substrate followed by controlled baking to form a film of the required carbon content and density. A process of this type based on sol-gel technology is described by B. E. Yoldas and T. W. O'Keeffe in Applied Optics, Vol. 18, No. 18, 15 Sep. 1979 to deposit a TiO₂—SiO₂ film on a substrate.

The deposition of a layer of density at least 1050 kg/m³ of a silicon compound containing 5 to 66% carbon atoms can also for example be applied to the silicon wafer substrate by spin coating, slot die coating, spray coating such as ultra-sonic spray coating, dip coating, angle-dependent dip coating, flow coating, capillary coating, roll coating or tampon printing. Some of these methods are appropriate for the coating of a single side of the silicon wafer substrate at a time; others can be used for the simultaneous coating of both sides of the substrate. The most appropriate method may be selected depending upon the type of solar cell architecture required and the need for single-side or double-side coating.

A spin coating process consists in dispensing a defined volume of solution on a substrate that is, or will be, submitted to spinning. The silicon wafer substrate is placed on a chuck, made of aluminum or Teflon, in a spin coater such as that sold by Chemat Technology as model KW-4A and held in place by vacuum suction. The solution of silicon-containing polymer having Si—H groups can be dispensed in static mode (the substrate is not spinning during the dispensing stage) or in dynamic mode (the substrate is subject to low speed spinning while dispensing the solution). The spinning process consists of first spinning the substrate at low speed (200-600 rpm) for a short time (2-10 s) and then spinning the substrate at high rate (1000-10000 rpm) for a longer time (10 s-60 s) to spread the solution evenly over the wafer substrate. The thickness of the resulting coating will depend upon the solid content of the resin solution and the spinning rate during the second spinning step. Coatings of dry film thickness in the range 40 to 500 nm are generally produced from hydrogen silsesquioxane resin solutions of concentration in the range 10 to 25% by weight. The spin coating process has the advantage of providing a very homogeneous coating in terms of thickness, with thickness variation typically in the <±1% to ±6%, although it has the disadvantages of long duration time and low product usage.

Spray coating is a suitable process for coating the silicon wafer substrate. An example of a suitable spray nozzle is a Burgener ARI MIST HP Serial 14.547 nebulizer. The solution of silicon-containing polymer having Si—H groups can be deposited by scanning the wafer at with the nebulized spray. Spraying has the advantage of relatively high coating rate while producing a homogeneous coating (±8%). A relatively dilute solution is preferred for spraying, for example a 4-10% by weight solution of the hydrogen silsesquioxane resin.

Slot die coating is another suitable process for coating the silicon wafer substrate. In the slot die process, the coating is squeezed out by gravity or under pressure through a slot and onto the substrate. The slot-die coater is a pre-metered coating method in which a precision pump delivers the coating solution to the slot die so that all of the coating solution metered to the die is applied to the web. Slot die coating also has the advantages of extremely high thickness homogeneity (<±1%) and a relatively high coating rate. A relatively dilute solution is preferred for slot die coating, for example a 1-15% by weight solution of the hydrogen silsesquioxane resin.

We have found that the density of the layer of silicon compound deposited in step (i) generally increases with increasing conversion of the organosilicon compound into a silicate or silica structure and consequent reduction of the percentage of carbon atoms in the layer deposited. The density of the layer of silicon compound deposited is preferably in the range 1200 to 2000 kg/m³, or alternatively in a range of from 1500 to 2000 kg/m³

In step (ii), the layer of silicon compound deposited in step (i) is thermally treated in an oxygen-containing atmosphere at a temperature of at least 600° C. (e.g., at least 700° C.) for 1 to 60 seconds, during which treatment the deposited layer is subject to a maximum temperature in the range 600 to 1050° C. This short time high temperature treatment can for example be achieved using an in-line furnace of the type used by the photovoltaic industry for the thermal contact annealing step of solar cell fabrication or using a RTP (Rapid Thermal Process) furnace, for example the RTP furnace provided by Surface Science Integration (SSI), 8552 Dysart Rd, El Mirage, 85335 Arizona, USA. The time of treatment at above 600° C. (e.g., at above 700° C., particularly at least 750° C.) is preferably less than 30 seconds and is most preferably less than 10 seconds, for example in the range 1 to 10 seconds. There may be no plateau in the furnace temperature profile; once the maximum temperature is reached, cool-down may take place immediately.

The oxygen-containing atmosphere used for the thermal treatment of step (ii) can for example contain 5 to 100%, preferably 10 to 50% oxygen. The oxygen is preferably mixed with an inert gas such as nitrogen. Conveniently the oxygen-containing atmosphere can be air.

The maximum temperature to which the silicon compound layer is subject in step (ii) is preferably at least 600° C., for example it may be in the range 600 to 1000° C. Preferably the silicon compound layer is treated at a temperature of at least 600° C. for 1 to 60 seconds, more preferably less than 30 seconds and most preferably less than 10 seconds. For example, step (ii) may comprise the thermally treating the deposited layer of silicon compound in an oxygen-containing atmosphere at a temperature of at least 700° C. for 1 to 60 seconds, during which treatment the deposited layer is subject to a maximum temperature in the range 700 to 1050° C., for example 750 to 1000° C. The thermal treatment in step (ii) is preferably sufficient to remove all carbon from the silicon compound, so that after thermal treatment the deposited layer of silicon compound contains no carbon as measured by XPS. The passivation layer formed after the thermal treatment of step (ii) essentially consists of silicon oxide dielectric material. We have found that having a long annealing step is not necessarily beneficial; if the silicon compound layer has been fully converted (all carbon has been eliminated), any longer exposure to oxygen at high temperature leads to a decrease in passivation performance. It is believed that the time of high temperature thermal treatment in step (ii) should preferably be the minimum time required for full carbon elimination, as measured by XPS.

Surprisingly we have found that silicon compound layers deposited in step (i) which contain at least 5% carbon according to the invention restructure into better and denser films after the short time firing in an oxygen rich atmosphere according to step (ii) than do films having very low carbon content before the firing step.

The thickness of the passivation layer of silicon oxide dielectric material produced is generally less than the thickness of the layer of silicon compound deposited in step (i). The passivation layer is preferably at least 50 nm thick and may be up to 600 nm thick. The thickness of the passivation layer of silicon oxide dielectric material is more preferably 150 nm to 400 nm.

In the production of a photovoltaic cell, a silicon wafer substrate coated with a passivation layer of a silicon oxide produced as described above has back contacts formed through the silicon oxide layer. To fully develop its passivation ability, the silicon wafer substrate coated with the passivation layer of silicon oxide is submitted to hydrogenation. This may be achieved either by forming gas annealing in an atmosphere containing hydrogen or by depositing a hydrogenated silicon nitride layer and firing the assembly of layers.

In a preferred process, an amorphous hydrogenated silicon nitride layer is deposited over the silicon oxide layer, and back contacts are formed through the silicon nitride and silicon oxide layers. The formation of such back contacts is a known process described for example in US-A-2009/0301557. Contacts are formed by forming holes in the dielectric silicon oxide layer and silicon nitride layer and depositing a layer of contacting material, thereby filling the holes. The holes may be formed by laser ablation, by applying an etching paste, or by mechanical scribing. The layer of contacting material, for example a metal such as aluminium, can be deposited by evaporation, sputtering, screen printing, inkjet printing, or stencil printing. It can be deposited locally essentially in the holes or as a continuous or discontinuous layer. After the contacting material has been applied, the photovoltaic cell can be subjected to a firing step, for example in the range 600 to 1000° C. for 5 to 60 seconds.

In an alternative hydrogenation process, the silicon dioxide layer is heated in an atmosphere comprising hydrogen. The atmosphere preferably contains 2 to 20% by volume hydrogen in an inert gas such as nitrogen. This type of hydrogenation process is preferably carried out at a temperature in the range 350° C. to 500° C., for example at about 400° C. The time for which hydrogenation is carried out can for example be in the range 10 to 60 minutes or more. However the formation of back contacts will require a subsequent firing step, for example in the range 600 to 1000° C. as described above.

The passivation layer of silicon oxide dielectric material formed by the process of the invention shows a negative fixed charge and has a low density of interface traps. We have found that photovoltaic cells, particularly solar cells, comprising the passivation layer of silicon oxide dielectric material formed by the process of the invention show improved passivation. Passivation can for example be measured by calculating the minority carrier lifetime using a μ-PCD (microwave detected photoconductive decay) device. The minority carrier lifetime is measured after hydrogenation without formation of back contacts. Increased minority carrier lifetime shows improved passivation. A suitable μ-PCD device is for example supplied by SemiLab under the trade mark WT-2000. In the μ-PCD technique, the time decay of photo carriers generated by a laser pulse is measured via the reflection of microwaves by the photo conductive wafer. The μ-PCD method typically operates at very high injection with a very short light pulse of only 200 ns.

In an alternative test procedure for measuring passivation, minority carrier lifetime is measured using a QSSPC measurement method (quasi steady state photoconductivity). QSSPC detects the changes in permeability of the sample and therefore the conductance via the coupling of the sample by a coil to a radio-frequency bridge. The exciting light is tuned down slowly, so that sample is always in a quasi steady state. In both test procedures, a longer lifetime indicates improved passivation.

We believe that the improved passivation results from a material containing negative fixed charges formed by firing silicon compound layers deposited in step (i) which contain at least 5% carbon in an oxygen rich atmosphere.

The density and sign of fixed charges and the density of interface traps are both parameters that characterize the quality of an oxide and the quality of the interface between the oxide and the silicon wafer. The measurement of these properties requires to build-up of very specific devices like a CMOS (Complementary metal-oxide-semiconductor) and to carry-out C-V (capacitance-Voltage) measurements on this device. To build a CMOS, an oxide layer (of thickness between 40 and 100 nm) is deposited onto a FZ wafer (for our measurement, we used p-doped wafers) having both sides polished; then, metal is deposited on both the wafer side and the oxide side to create a CMOS structure. When applying a voltage to a CMOS structure and measuring capacitance (moving from negative voltage to positive voltage and vice-versa), we obtain curves showing hysteresis.

With a p-type wafer, when a negative voltage is applied to the electrodes, we have accumulation of the majority carriers (the holes) to the interface between the wafer and the silicon oxide also the assembly behave like a capacitor of dielectric thickness being equal to the thickness of the oxide itself. When decreasing voltage to zero, the capacitance decreases to reach a minimum; when applying positive voltage, we are in inversion mode which means that minority carrier (electrons in our case) move to oxide silicon interface, and the capacitance increase again. For CV measurements, a high frequency component is applied to the DC component, changing the shape of the CV curve shown in FIGS. 3 and 4. The part of the curve representing applied negative voltage is not affected because majority carrier have a high mobility and can follow the rapid change in voltage. This is not the case for minority carriers so that the capacitance measured will stay flat as shown at 6 and 7 in FIGS. 3 and 4.

If the flat band voltage (voltage associated to the decrease in capacitance) is negative as shown in FIG. 3 when using a p-type wafer, this means that built-in fixed charges in the dielectric are of positive sign, the charge density being calculated from the flat band voltage value. Such positive fixed charges (and hence negative flat band voltage) are typical of silicon oxide layers known for use in PERC structure photovoltaic cells.

If the flat band voltage (voltage associated to the decrease in capacitance) is positive as shown in FIG. 4 when using a p-type wafer, this means that built-in fixed charge in the dielectric are of negative sign. The charge density can be calculated from the flat band voltage value. Such negative fixed charges (and hence positive flat band voltage) are found for the silicon oxide passivation layers produced by the process of the invention, for example the silicon oxide layer formed in Example 1. The silicon wafer coated with a passivation layer of a silicon oxide according to the present invention typically has a density of fixed negative charges of at least 1×10 cm⁻² and typically between 2×10¹¹ cm⁻² and 1×10¹² cm^{-2.} Fixed negative charge is an advantageous property in a PERC structure when using a p-doped silicon wafer because the built-in electric favour the charge collection at the interface.

The hysteresis is associated with the density of interface traps that fill and empty depending on the sign of voltage applied. When positive fixed charges are present, hysteresis is counter clockwise as in FIG. 32 while when negative charge are present, hysteresis is clockwise as in FIG. 4. The density of interface trap can be calculated from this hysteresis. The silicon wafer coated with a passivation layer of a silicon oxide according to the present invention typically has a density of interface traps below 7×10¹⁰ eV⁻¹ cm⁻²

The invention is illustrated by the following Examples, in which percentages of elements express the atomic fraction of atoms in the layer, excluding hydrogen which is not detected by XPS.

XPS analysis was performed using an Axis Ultra spectrometer (Kratos Analytical). Samples were irradiated with monochromated x-rays (Al Kα, 1486.6 eV) with photoelectrons analyzed from a selected area 700 μm by 300 μm, with a take-off-angle of 90°. Experience with similar specimens indicated that differential charging was likely. To obtain good spectra the instrument's charge neutralization system was used. Each analysis position was analyzed in the survey mode (Pass Energy 160 eV) to determine the elements that were present at the surface and their relative concentrations. Casa XPS (Casa Software Ltd) data processing software was used to calculate the area under peaks representative of elements detected, which were then normalized to take into account relative sensitivity to provide relative concentrations. Each analysis position was also analyzed in the high resolution mode (Pass Energy 20 eV) to determine more detailed information on the elements present at the surface. The time delay between film formation and XPS measurement was kept minimum. Samples were stored in a clean plastic box right after SiOx film formation to minimize contamination. No extra treatment was applied after film formation process to avoid further samples manipulation.

Thermal treatment in the Examples was by RTP furnace supplied by SSI. Where a 1 second value is stated for time at the maximum set point temperature, cool-down took place immediately once the maximum temperature was reached; even if thermal inertia of the RTP furnace is low, we may consider that the wafer is exposed at the peak temperature for about one 1 second.

### EXAMPLE 1

The apparatus of FIG. 1 was used to deposit a layer of an organosilicon compound on a conductive silicon wafer substrate. The dielectric housing (14) defining the plasma tube (13) was 18 mm in diameter. This housing (14) is made of quartz. The electrodes (11, 12) were each 1 mm diameter and were connected to the Plasma Technics ETI110101 unit operated at 20 kHz and maximum power of 100 watts. Helium process gas was flowed through chamber (19) and thence through channels (16, 17) at 2 L/min. The channels (16, 17) were each 2 mm in diameter, the electrodes (11, 12) being localized in the centre of each channel. The length of the channels was 30 mm. The tip of each needle electrode (11, 12) was positioned close to the exit of the channel (16, 17 respectively) at a distance 0.5 mm outside the channel exit.

The atomiser (21) was the An Mist HP pneumatic nebuliser supplied by Burgener Inc. Tetramethyltetracyclosiloxane was supplied to the atomiser (21) at 2 μL/m. Helium was fed to the atomiser (21) as atomising gas at 2.2 slm-. The gap (30) between quartz housing (14) and the silicon wafer substrate was 2 mm.

4 inches (10 cm) diameter Float Zone silicon circular wafers 350 nm thick were used as substrate to produce an assembly suitable for surface passivation measurement. Wafers were cleaned with a standard Pyrana recipe used in microelectronics followed by a 5 seconds dip in a 5% by weight HF solution. Two smooth organosilicon compound films were deposited on both the top side and the rear side of the wafer, deposition time being controlled to 660 seconds to have organosilicon compound films of thickness ˜500 nm prior the firing step. The carbon content of the organosilicon compound layer was measured by XPS as 20.5%. The density of the organosilicon compound layer was measured by measuring the weight of the film using a Sartorius scale with a precision of 1×10⁻⁵ gram and the film thickness using a Jobin Yvon UVsel spectroscopic Ellipsometer and was found to be 1290 kg/m³

The coated wafer was thermally treated in air by exposure of both organosilicon compound layers to a maximum temperature of 850° C. for 1 second. The time to reach maximum temperature was 6 seconds. The organosilicon compound layers were densified and converted to silicon oxide. The silicon oxide layers produced had no carbon content detectable by XPS Each silicon oxide layer was ˜250 nm thick.

The silicon wafer substrate coated on both sides with silicon oxide was hydrogenated by exposure to 10% by volume H₂ diluted in N₂ at 400° C. for 30 minutes. The passivation performance was measured by μ-PCD and was found to have a lifetime value of 170 μs.

### EXAMPLES 2 TO 5

Example 1 was repeated using varying flow rates of the tetramethyltetracyclosiloxane (TMCTS) precursor as shown in Table 1. In each Example the carbon content of the organosilicon compound layer deposited in step (i) was measured by XPS and the density of this organosilicon compound layer was measured; the results are shown in Table 1.

For each of Examples 1 to 5 the lifetime of a surface passivation testing assembly comprising the silicon wafer substrate coated on both sides with silicon oxide layers and hydrogenated was measured using a p-PCD device. The results are shown in Table 1.

TABLE 1

| Example | TMCTS flow | Carbon content | Density after | Lifetime |
|---|---|---|---|---|
| No. | μl/min | by XPS (%) | step (i) | in μs |
| 1 | 2 | 20.5 | 1290 | 170 |
| 2 | 6 | 26 | 1550 | 255 |
| 3 | 9 | 29 | Not measured | 280 |
| 4 | 12 | 33 | 1650 | 250 |
| 5 | 50 | 31.5 | 1050 | 55 |

### EXAMPLES 6 AND 7

Organosilicon compound layers were deposited on silicon wafer substrates using the process of Example 3, that is the conditions of Example 1 but with a TMCTS flow rate of 6 μl/min depositing an organosilicon compound layer of carbon content 26%.

Each coated wafer was thermally treated in air by exposure of both organosilicon compound layers to a maximum temperature of 850° C. The time to reach maximum temperature is 6 seconds. The time of firing at the maximum temperature of 850° C. was varied as shown in Table 2.

The silicon oxide layer at the back face of each silicon wafer substrate was hydrogenated by exposure to 10% by volume H₂ diluted in N₂ at 400° C. for 30 minutes and lifetime measured by μ-PCD.

For each of Examples 3, 6 and 7 the minority carrier lifetime of the testing assembly comprising the silicon wafer substrate coated with silicon oxide layers and hydrogenated was measured using a μ-PCD device. The results are shown in Table 2.

TABLE 2

| Example | Time at 850° C. | Lifetime |
|---|---|---|
| No. | in seconds | in μs |
| 3 | 1 | 255 |
| 6 | 6 | 110 |
| 7 | 60 | 50 |

### EXAMPLE 8

The apparatus of FIG. 1 was used to deposit a layer of an organosilicon compound on 4 inches (10 cm) diameter Float Zone circular silicon wafer substrates 350 nm thick. The dielectric housing (14) defining the plasma tube (13) was 18 mm in diameter. This housing (14) is made of quartz. The electrodes (11, 12) were each 1 mm diameter and were connected to the Plasma Technics ETI110101 unit operated at 20 kHz and maximum power of 100 watts. Helium process gas was flowed through chamber (19) and thence through channels (16, 17) at 10 L/min. The channels (16, 17) were each 2 mm in diameter, the electrodes (11, 12) being localized in the centre of each channel. The length of the channels was 30 mm. The tip of each needle electrode (11, 12) was positioned close to the exit of the channel (16, 17 respectively) at a distance 0.5 mm outside the channel exit.

The atomiser (21) was the An Mist HP pneumatic nebuliser supplied by Burgener Inc. Tetramethyltetracyclosiloxane was supplied to the atomiser (21) at 6 μL/m. Helium was fed to the atomiser (21) as atomising gas at 2.2 L/m. The gap (30) between quartz housing (14) and the silicon wafer substrate was 1.25 mm. Deposition time was controlled to 660 seconds to give films of thickness of ˜500 nm prior to thermal treatment.

Smooth organosilicon compound layers were deposited on both the top side and the rear side of the wafer under such process conditions. The organosilicon compound layers had a carbon content of 27%.

The coated silicon wafer substrate was thermally treated in air by exposure of both silicon compound layers to a maximum temperature of 850° C. for 1 second. The time to reach maximum temperature is 6 seconds. The silicon compound layers were densified and converted to silicon oxide.

Each coated silicon wafer was overcoated on both sides with a 80 nm thick SiₓN_{y}H_{z} film deposited by a low pressure PE-CVD (Plasma Enhanced Chemical Vapor Deposition) technique.

The lifetime of the resulting structure was measured, using the QSSPC measurement method, as 270 μs for an injection level of 2×10¹⁵ cm⁻³

As a comparison, the lifetime of a structure comprising a silicon wafer coated on both sides with a silicon oxide layer deposited by atmospheric pressure chemical vapor deposition (AP-CVD) and overcoated on both sides with a 80 nm thick SiₓN_{y}H_{z} film was measured, using the QSSPC measurement method. This structure was supplied as suitable for a PERC (Passivated Emitter and Rear Contact) solar cell. Its lifetime was measured as 100 μs for a same injection level of 2×10¹⁵ cm⁻³

### EXAMPLE 9

The apparatus described in example 8 (gap of 1.25 mm) was operated using Argon instead of Helium as process gas. The flow of Argon was set to 2.5 L/min through the channels and 0.3 L/min through the atomizer. The TMCTS flow was set to 12 μL/min. Under these conditions a carbon rich organosilicon compound was deposited: carbon content measured in the film is equal to ˜28%.

The coated silicon wafer substrate produced was thermally treated in air as described in example 8. The resulting coated wafer was overcoated on both sides with an 80 nm thick SiₓN_{y}H_{z} film as described in Example 8. The lifetime of the resulting structure, after the step of overcoating on both sides with an 80 nm thick SiₓN_{y}H_{z} film, was measured as 500 μs for an injection level of 2e15 cm⁻³. It will be seen that this lifetime is 5 times larger than reference PERC oxide structure measured in Example 8 for the same minority carrier injection level.

### EXAMPLES 10 AND 11

The apparatus and process conditions of example 9 were used to deposit a layer of an organosilicon compound on a 12.5×12.5 cm² pseudo-square monocrystalline silicon wafer substrate 200 μm thick. Deposition time was controlled to 360 seconds in Example 10 and to 620 seconds in Example 11. In each case a smooth organosilicon compound coating was deposited.

This non-local thermal equilibrium atmospheric pressure plasma deposition process was used to deposit a single silicon compound layer on the silicon wafer substrate as the back side of the solar cell as the first step of a PERC architecture built-up, the front side being a standard state of the art front cell configuration being made of the emitter and of a antireflective SiN:H coating.

The coated silicon wafer substrate was thermally treated in air by exposure of rear organosilicon compound layer to a maximum temperature of 820° C. for 1 second. The time to reach maximum temperature was 6 seconds. The silicon compound layer was densified and converted to a silicon oxide. The silicon oxide layer produced had no carbon content detectable by XPS. The silicon oxide layer in Example 10 was 150 nm thick and the silicon oxide layer in Example 11 was 300 nm thick.

The rear side silicon oxide layer was overcoated with an 80 nm thick SiₓN_{y}H_{z} film by a low pressure PE-CVD technique.

Photovoltaic cells were prepared from the resulting structure by opening the rear SiOx/SiNy:H stack by laser ablation followed by metallisation via aluminium deposition by screen printing and firing in a belt furnace at a peak temperature of 800° C.

The cells were then characterized through electrical measurements. Cell performances are expressed by the short circuit current, I_{sc} and open circuit voltage V_{oc}. The I_{sc} reflects the quality of the reflector at the rear side and is associated to thickness of the silicon oxide layer and its optical index. The V_{oc} value reflects the quality of rear surface passivation.

The short circuit current, I_{sc} and open circuit voltage V_{oc} of reference BSF cells and commercially available PERC cells incorporating state of the art AP-CVD silicon oxide were also measured. The reference BSF cells were produced with the same batch of wafer but having on the rear side a BSF passivation structure instead of the silicon oxide/silicon nitride PERC architecture—BSF is the standard passivation structure presently used in the photovoltaic industry). Light I-V measurement of the PV cell is carried-out under controlled illumination. A voltage source is set up to supply a voltage sweep to the cell and the resulting current is measured. The voltage source is swept from V1=0 to V2=VOC. When the voltage source is 0 (V1=0), the current is equal to the short-circuit current (ISC). When the voltage source is an open circuit (V2=VOC), then the current is equal to zero (I2=0). This measurement is described in the standard IEC 60904-1 (Part 1—Measurements of photovoltaic current-voltage characteristics). The results are shown in Table 3, each result being the mean of 4 cells tested.

TABLE 3

| | I_{sc} (mA/cm²) | open circuit voltage (mV) |
|---|---|---|
| Example 9 | 36.9 | 638 |
| Example 10 | 37.1 | 637 |
| BSF reference | 36.1 | 623 |
| PERC reference | 37.3 | 639 |

It can be seen from Table 3 that the cells having SiOₓ films according to the present invention have similar performance to the PERC cells incorporating state of the art AP-CVD oxide and better performance than reference cells having BSF passivation, both in terms of short circuit current, I_{sc} and open circuit voltage V_{oc}.

### EXAMPLES 12 AND 13

The apparatus and process conditions of example 8 have been used except that a shorter deposition time was used, to coat a silicon wafer substrate in Examples 12 and 13 with silicon oxide layers have thicknesses of 34 nm and 41 nm respectively)

For capacitance-voltage measurement, a platinum electrode was attached to the silicon oxide layer and the opposite face of the silicon wafer substrate was coated with aluminium. The capacitance of the silicon oxide/silicon wafer stack is measured as a function of the applied voltage (up to saturation limit in both polarities) on the structure to measure the capacitance of the layer. From the hysteresis (observed when scanning voltage from negative to positive voltage and vice-versa) and voltage corresponding to the flat band transition, we can extract
i) the interface density of states (DIT) and
ii) The polarity of the fixed charges and iii) their density.
   These results are reported in Table 4.

The same capacitance-voltage measurements were also made on two PERC structures referenced as PERC1 and PERC 2 incorporating state of the art AP-CVD silicon oxide layers of similar thickness, and these results are also reported in Table 4.

TABLE 4

| | | | Flat band | Flat band | |
|---|---|---|---|---|---|
| | | | voltage | voltage | |
| | Oxide | | expressed in | expressed in | |
| Sample | thickness | Dit | volts (forward | volts (reverse | Hysteris |
| reference | [nm] | (eV⁻¹, cm⁻²) | voltage sweep) | voltage sweep) | [rev-forw] |
| PERC 1 | 43.23 | 1.31 × 10¹¹ | −5.33 | −4.47 | 0.86 |
| PERC 2 | 57.44 | 1.02 × 10¹¹ | −9.76 | −8.62 | 1.14 |
| example 12 | 34.23 | 9.28 × 10¹⁰ | 0.23 | −0.30 | −0.53 |
| example 13 | 40.90 | 7.37 × 10¹⁰ | 0.44 | −0.02 | −0.46 |

It will be observed that DIT of the structure made according to the present invention is lower, which implies a better material and interface quality. The forward and reverse voltage associated to the hysteresis are also reported in Table 4. It can be seen that the hysteresis measured on our material is opposite to the hysteresis measured on the structure having a state of the art AP-CVD silicon oxide layer, which means that fixed charges in the material of this invention and in the reference have opposite sign. Generally, it is accepted that deposited silicon oxide layers have fixed positive charges. We believe that the silicon oxide layers produced according to the present invention show fixed negative charge and we believe that this is a cause of the good silicon surface passivation results obtained using films deposited using the method of this invention.

The invention may be any one of the following numbered aspects:
1. A process for the production of a silicon wafer coated with a passivation layer of a silicon oxide, comprising the steps of
   (i) depositing a layer of density at least 1050 kg/m³ of a silicon compound containing 5 to 66% carbon atoms (calculated as the proportion of carbon atoms in the deposited layer to total atoms excluding hydrogen) on a silicon wafer substrate and
   (ii) thermally treating the deposited layer of silicon compound in an oxygen-containing atmosphere at a temperature of at least 600° C. for 1 to 60 seconds, during which treatment the deposited layer is subject to a maximum temperature in the range 600 to 1050° C.
2. A process according to Aspect 1 characterized in that the density of the deposited layer of silicon compound is in the range 1200 to 2000 kg/m³
3. A process according to Aspect 2 characterised in that the density of the deposited layer of silicon compound is at least 1500 kg/m³
4. A process according to any of Aspects 1 to 3 characterised in that the silicon compound deposited in step (i) comprises silicon, oxygen and carbon atoms and optionally hydrogen atoms.
5. A process according to any of Aspects 1 to 4, characterized in that the silicon compound deposited in step (i) comprises a silicon-containing polymer having Si—H groups.
6. A process according to any of Aspects 1 to 5 characterised in that the percentage of carbon atoms in the layer deposited in step (i) (calculated as the proportion of carbon atoms in the deposited layer to total atoms excluding hydrogen) is in the range 5 to 30%.
7. A process according to any of Aspects 1 to 6 characterised in that the layer of silicon compound is deposited from a non-local thermal equilibrium atmospheric pressure plasma containing an organosilicon compound.
8. A process according to Aspect 7 characterised in that the organosilicon compound is tetramethylcyclotetrasiloxane (CH₃(H)SiO)₄ and the percentage of carbon atoms in the layer deposited in step (i) (calculated as the proportion of carbon atoms in the deposited layer to total atoms excluding hydrogen) is less than 33%.
9. A process according to Aspect 7 characterised in that the organosilicon compound is tetraethyl orthosilicate Si(OC₂H₅)₄ and the percentage of carbon atoms in the layer deposited in step (i) (calculated as the proportion of carbon atoms in the deposited layer to total atoms excluding hydrogen) is less than 60%.
10. A process according to Aspect 7 characterised in that the organosilicon compound is hexamethyldisiloxane ((CH₃)₃)Si)₂O and the percentage of carbon atoms in the layer deposited in step (i) (calculated as the proportion of carbon atoms in the deposited layer to total atoms excluding hydrogen) is less than 65%.
11. A process according to any of Aspects 7 to 10 characterised by applying a radio frequency high voltage to at least one needle electrode (11) positioned within a dielectric housing (14) having an inlet and an outlet while causing a process gas to flow from the inlet through a channel (16) past the electrode (11) to the outlet, thereby generating a non-local thermal equilibrium atmospheric pressure plasma, incorporating the organosilicon compound in the non-local thermal equilibrium atmospheric pressure plasma so that the organosilicon compound interacts with the non-local thermal equilibrium atmospheric pressure plasma to generate activated organosilicon compound species and organosilicon compound fragments, and positioning the silicon wafer substrate (25) adjacent to the outlet of the dielectric housing so that the surface of the silicon wafer substrate is in contact with activated organosilicon compound species and organosilicon compound fragments generated by plasma-organosilicon compound interaction.
12. A process according to Aspect 11 characterised in that the non-local thermal equilibrium atmospheric pressure plasma extends to the outlet of the dielectric housing so that the surface of the silicon wafer substrate is in contact with the plasma.
13. A process according to Aspect 11 or Aspect 12 characterised in that the organosilicon compound is introduced into the non-local thermal equilibrium atmospheric pressure plasma via an atomiser (21) positioned within the dielectric housing (14).
14. A process according to Aspect 13 characterised in that a gas is used to atomise the surface treatment agent in the atomiser (21).
15. A process according to any of Aspects 7 to 14 characterised in that the organosilicon compound is introduced into the non-local thermal equilibrium atmospheric pressure plasma at 2 to 14 μL/minute.
16. A process according to any of Aspects 10 to 15 wherein the process gas is fed to the inlet of the dielectric housing at 1 to 15 L/minute.
17. A process according to any of Aspects 1 to 16 characterised in that in step (ii) the deposited layer is subject to a maximum temperature in the range 700 to 1000° C.
18. A process according to any of Aspects 1 to 17 characterised in that the deposited layer of silicon compound is treated at a temperature of at least 700° C. for 1 to 60 seconds.
19. A process according to any of Aspects 1 to 18 characterised in that after thermal treatment the deposited layer of silicon compound contains no carbon as measured by X-ray photoelectron spectroscopy.
20. A process for the production of a photovoltaic cell, wherein a silicon wafer coated with a passivation layer of a silicon oxide is produced by the process of any of Aspects 1 to 19, the silicon oxide layer is hydrogenated and back contacts are formed through the silicon oxide layer.
21. A process according to Aspect 20 characterised in that the silicon oxide layer is hydrogenated by depositing a layer of a silicon nitride over the silicon oxide layer, and back contacts are formed through the silicon nitride and silicon oxide layers

1. A process for the production of a silicon wafer coated with a passivation layer of a silicon oxide, comprising the steps of
(i) depositing a layer of density at least 1050 kg/m³ of a silicon compound containing 5 to 66% carbon atoms (calculated as the proportion of carbon atoms in the deposited layer to total atoms excluding hydrogen) on a silicon wafer substrate and
(ii) thermally treating the deposited layer of silicon compound in an oxygen-containing atmosphere at a temperature of at least 600° C. for 1 to 60 seconds, during which treatment the deposited layer is subject to a maximum temperature in the range 600 to 1050° C.

2. A process according to claim 1 characterized in that the density of the deposited layer of silicon compound is in the range 1200 to 2000 kg/m³; or characterised in that the density of the deposited layer of silicon compound is in the range 1200 to 2000 kg/m³ and is at least 1500 kg/m³.

3. A process according to claim 1 characterised in that the silicon compound deposited in step (i) comprises silicon, oxygen and carbon atoms and optionally hydrogen atoms.

4. A process according to claim 1, characterized in that the silicon compound deposited in step (i) comprises a silicon-containing polymer having Si—H groups.

5. A process according to any of claims 1 to 4 characterised in that the percentage of carbon atoms in the layer deposited in step (i) (calculated as the proportion of carbon atoms in the deposited layer to total atoms excluding hydrogen) is in the range 5 to 30%.

6. A process according to claim 1 characterised in that the layer of silicon compound is deposited from a non-local thermal equilibrium atmospheric pressure plasma containing an organosilicon compound; or characterised in that the layer of silicon compound is deposited from a non-local thermal equilibrium atmospheric pressure plasma containing an organosilicon compound and characterised in that the organosilicon compound is tetramethylcyclotetrasiloxane (CH₃(H)SiO)₄ and the percentage of carbon atoms in the layer deposited in step (i) (calculated as the proportion of carbon atoms in the deposited layer to total atoms excluding hydrogen) is less than 33%; or characterised in that the layer of silicon compound is deposited from a non-local thermal equilibrium atmospheric pressure plasma containing an organosilicon compound and characterised in that the organosilicon compound is tetraethyl orthosilicate Si(OC₂H₅)₄ and the percentage of carbon atoms in the layer deposited in step (i) (calculated as the proportion of carbon atoms in the deposited layer to total atoms excluding hydrogen) is less than 60%; or characterised in that the layer of silicon compound is deposited from a non-local thermal equilibrium atmospheric pressure plasma containing an organosilicon compound and characterised in that the organosilicon compound is hexamethyldisiloxane ((CH₃)₃)Si)₂O and the percentage of carbon atoms in the layer deposited in step (i) (calculated as the proportion of carbon atoms in the deposited layer to total atoms excluding hydrogen) is less than 65%.

7. A process according to claim 6 characterised by applying a radio frequency high voltage to at least one needle electrode (11) positioned within a dielectric housing (14) having an inlet and an outlet while causing a process gas to flow from the inlet through a channel (16) past the electrode (11) to the outlet, thereby generating a non-local thermal equilibrium atmospheric pressure plasma, incorporating the organosilicon compound in the non-local thermal equilibrium atmospheric pressure plasma so that the organosilicon compound interacts with the non-local thermal equilibrium atmospheric pressure plasma to generate activated organosilicon compound species and organosilicon compound fragments, and positioning the silicon wafer substrate (25) adjacent to the outlet of the dielectric housing so that the surface of the silicon wafer substrate is in contact with activated organosilicon compound species and organosilicon compound fragments generated by plasma-organosilicon compound interaction.

8. A process according to claim 7 characterised in that the non-local thermal equilibrium atmospheric pressure plasma extends to the outlet of the dielectric housing so that the surface of the silicon wafer substrate is in contact with the plasma; or characterised in that the organosilicon compound is introduced into the non-local thermal equilibrium atmospheric pressure plasma via an atomiser (21) positioned within the dielectric housing (14); or characterised in that the non-local thermal equilibrium atmospheric pressure plasma extends to the outlet of the dielectric housing so that the surface of the silicon wafer substrate is in contact with the plasma and characterised in that the organosilicon compound is introduced into the non-local thermal equilibrium atmospheric pressure plasma via an atomiser (21) positioned within the dielectric housing (14).

9. A process according to claim 8 characterised in that a gas is used to atomise the surface treatment agent in the atomiser (21).

10. A process according to claim 6 characterised in that the organosilicon compound is introduced into the non-local thermal equilibrium atmospheric pressure plasma at 2 to 14 μL/minute.

11. A process according to claim 7 wherein the process gas is fed to the inlet of the dielectric housing at 1 to 15 L/minute.

12. A process according to claim 1 characterised in that in step (ii) the deposited layer is subject to a maximum temperature in the range 700 to 1000° C.; or characterised in that the deposited layer of silicon compound is treated at a temperature of at least 700° C. for 1 to 60 seconds; or characterised in that in step (ii) the deposited layer is subject to a maximum temperature in the range 700 to 1000° C. and characterised in that the deposited layer of silicon compound is treated at a temperature of at least 700° C. for 1 to 60 seconds.

13. A process according to claim 1 characterised in that after thermal treatment the deposited layer of silicon compound contains no carbon as measured by X-ray photoelectron spectroscopy.

14. A process for the production of a photovoltaic cell, wherein a silicon wafer coated with a passivation layer of a silicon oxide is produced by the process of claim 1, the silicon oxide layer is hydrogenated and back contacts are formed through the silicon oxide layer.

15. A process according to claim 14 characterised in that the silicon oxide layer is hydrogenated by depositing a layer of a silicon nitride over the silicon oxide layer, and back contacts are formed through the silicon nitride and silicon oxide layers.
